(19) United States
(12) Patent Application Publication
(10) Pub. No.: US 2025/0294692 A1
(43) Pub. Date: Sep. 18, 2025

(54) ELECTRONIC DEVICE SYSTEM AND ELECTRONIC DEVICE

(71) Applicant: Panasonic Intellectual Property Management Co., Ltd., Osaka (JP)

(72) Inventor: Akira Yamaguchi, Osaka (JP)

(21) Appl. No.: 18/606,618

(22) Filed: Mar. 15, 2024

(51) Int. Cl. H05K 5/02; H05K 5/00

(52) U.S. Cl. CPC H05K 5/0247; H05K 5/0217; H05K 5/30

(57) ABSTRACT

An electronic device system includes: a first housing that includes a first processor and a first connector including a plurality of first terminals; and a second housing that is connectable to the first housing and includes first circuitry, second circuitry, and a second connector. The first circuitry includes an element for identifying the type of the second housing. The second circuitry includes one or more modules. The second connector includes a plurality of second terminals. When the second connector is connected to the first connector, the first processor reads out information about the element from the first circuitry to identify the type of the second housing. The first processor communicates with the second circuitry via one or more second terminals connected to the one or more modules used for the type identified, but not via a second terminal other than the one or more second terminals.

### FIELD

The present disclosure relates to an electronic device system and electronic device used for a moving body.

### BACKGROUND

Patent Literature 1 discloses a measurement system that identifies the type of an external device based on a terminal voltage generated at a measurement device-side type identification connection terminal in a state in which predetermined current flows through a path leading to a measurement device-side connection terminal connected to an external device-side connection terminal, via a series circuit of a resistor and a light emitting diode and the external device-side connection terminal.

Patent Literature 2 discloses a hardware module for adding a function to a device such as a television, DVD player, or the like.

### CITATION LIST

### Patent Literature

[Patent Literature 1] Japanese Patent No. 4230589

[Patent Literature 2] Japanese Unexamined Patent Application Publication (Translation of PCT Application) No. 2010-539854

### SUMMARY

### Technical Problem

A non-limiting and exemplary embodiment according to an aspect of the present disclosure provides an electronic device system and electronic device that easily fulfill a function of one or more modules included in a second housing connected to a first housing.

### Solution to Problem

An electronic device according to an aspect of the present disclosure includes a first housing and a second housing. The first housing is provided to a moving body and includes a first processor and a first connector including a plurality of first terminals. The second housing is provided to the moving body and connectable to the first housing. The second housing includes first circuitry, second circuitry, and a second connector. The first circuitry includes an element for identifying the type of the second housing. The second circuitry is connected to one or more modules among a plurality of modules having different functions. The second connector includes a plurality of second terminals connectable to the plurality of first terminals and connects the first connector to the first circuitry and the second circuitry. When the second connector is connected to the first connector, the first processor reads out information about the element from the first circuitry to identify the type of the second housing. The first processor communicates with the second circuitry via, among the plurality of second terminals, one or more second terminals connected to the one or more modules used for the type identified, and does not communicate with the second circuitry via a second terminal other than the one or more second terminals.

An electronic device according to an aspect of the present disclosure is provided to a moving body, includes a first processor and a first connector including a plurality of first terminals, and is connectable to a predetermined electronic device that is provided to the moving body. The predetermined electronic device includes first circuitry, second circuitry, and a second connector. The first circuitry includes an element for identifying the type of the predetermined electronic device. The second circuitry includes one or more modules among a plurality of modules having different functions. The second connector includes a plurality of second terminals connectable to the plurality of first terminals and connects the first connector to the first circuitry and the second circuitry. When the second connector is connected to the first connector, the first processor reads out information about the element from the first circuitry to identify the type of the predetermined electronic device. The first processor communicates with the second circuitry via, among the plurality of second terminals, one or more second terminals connected to the one or more modules used for the type identified, and does not communicate with the second circuitry via a second terminal other than the one or more second terminals.

An electronic device according to an aspect of the present disclosure is provided to a moving body, connectable to a predetermined electronic device that is provided to the moving body, and includes first circuitry and second circuitry. The first circuitry includes an element for identifying the type of the electronic device. The second circuitry includes one or more modules among a plurality of modules having different functions. When the electronic device is connected to the predetermined electronic device, the first circuitry provides information about the element to the predetermined electronic device.

It should be noted that general or specific aspects of the present disclosure may be realized as a system, method, integrated circuit, computer program, recording medium, storage, or any given combination thereof.

Additional benefits and advantages of the disclosed embodiments will be apparent from the Specification and Drawings.

The benefits and/or advantages may be individually obtained by the various embodiments and features of the Specification and Drawings, which need not all be provided in order to obtain one or more of such benefits and/or advantages.

### Advantageous Effects

An electronic device system and electronic device according to an aspect of the present disclosure have the advantage that a function of one or more modules included in a second housing connected to a first housing is easily fulfilled.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1A is a schematic diagram illustrating a state in which a first housing and a second housing are separated from each other in an electronic device system according to Embodiment 1.

FIG. 1B is a schematic diagram illustrating a state in which the first housing and the second housing are connected to each other in the electronic device system according to Embodiment 1.

FIG. 2 is a block diagram illustrating a configuration of the electronic device system according to Embodiment 1.

FIG. 3 is a diagram illustrating an example of a plurality of types of second housings that can be used in the electronic device system according to Embodiment 1.

FIG. 4 is a diagram for describing an identification process for identifying the type of the second housing in the electronic device system according to Embodiment 1.

FIG. 5 is a schematic diagram illustrating a usage example of the electronic device system according to Embodiment 1.

FIG. 6 is a flowchart illustrating an operation example of the electronic device system according to Embodiment 1.

FIG. 7 is a block diagram illustrating a configuration of an electronic device system according to Embodiment 2.

### DESCRIPTION OF EMBODIMENTS

Hereinafter, embodiments of the present disclosure are described with reference to the Drawings.

It should be noted that each embodiment described below shows a general or specific example of the present disclosure. The numerical values, shapes, materials, constituent elements, the arrangement and connection of the constituent elements, steps, order of the steps etc., indicated in the following embodiments are mere examples, and therefore do not intend to limit the scope of the Claims. Moreover, among the constituent elements in the following embodiments, constituent elements not recited in any one of the independent claims defining the broadest concept of the present disclosure are described as arbitrary constituent elements.

### Embodiment 1

### (1. Configuration)

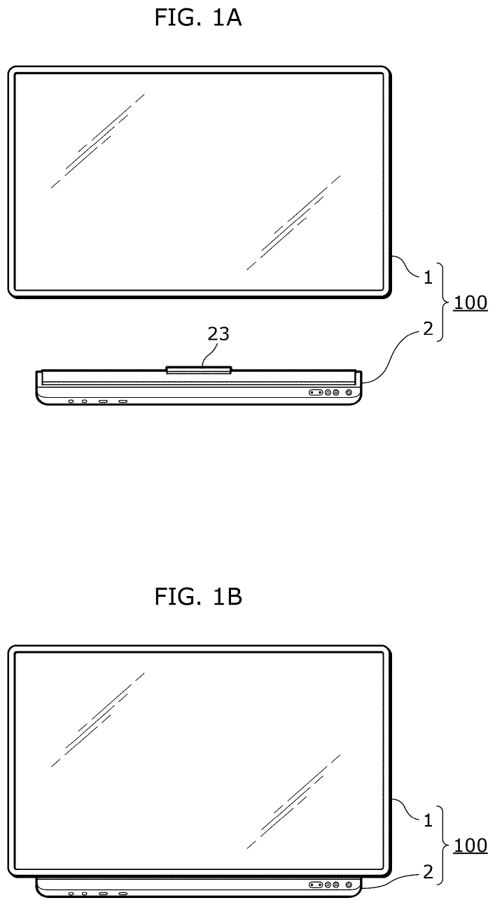

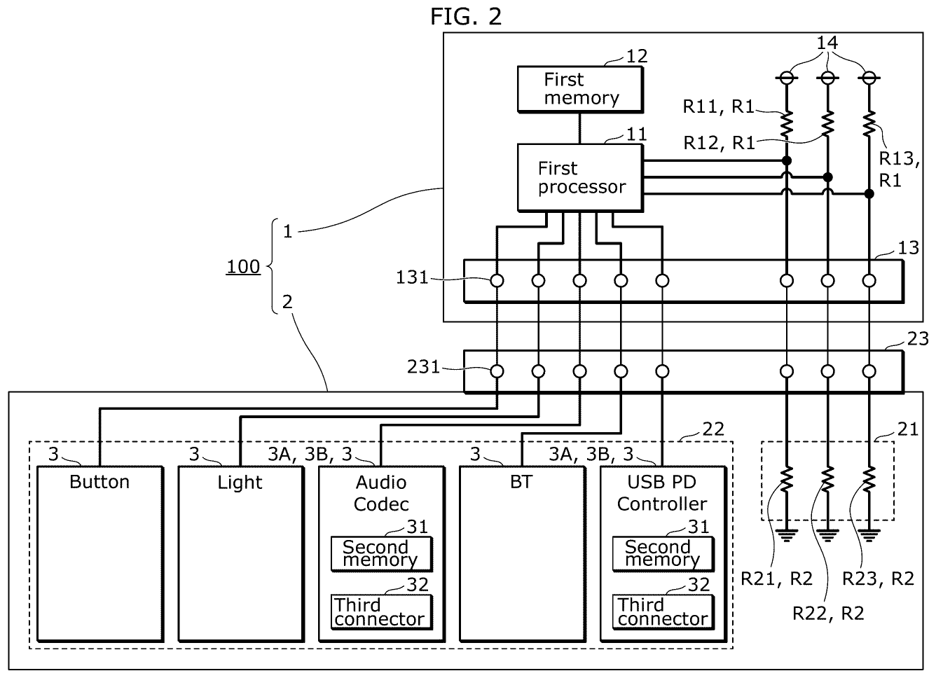

Hereinafter, electronic device system 100 according to Embodiment 1 is described with reference to the Drawings. FIG. 1A is a schematic diagram illustrating a state in which first housing 1 and second housing 2 are separated from each other in electronic device system 100 according to Embodiment 1. FIG. 1B is a schematic diagram illustrating a state in which first housing 1 and second housing 2 are connected to each other in electronic device system 100 according to Embodiment 1. FIG. 2 is a block diagram illustrating a configuration of electronic device system 100 according to Embodiment 1. It should be noted that “connect” in the following description means, unless otherwise specified, “connect mechanically and electrically”.

Electronic device system 100 is a system that is installed in a moving body and includes first housing 1 and second housing 2, as illustrated in FIG. 1A, FIG. 1B, and FIG. 2. In Embodiment 1, a moving body in which electronic device system 100 is installed is an airplane. It should be noted that the moving body in which electronic device system 100 is installed is not limited to an airplane, and examples of the moving body may include a large vehicle such as a bus, train, ship, and the like.

First housing 1 is, for example, a display such as a liquid crystal display or organic electroluminescence (EL) display. In Embodiment 1, first housing 1 is attached to, for example, a backside of a backrest of a seat in the moving body. Then, first housing 1 is used by a user sitting on a seat located behind the seat to which first housing 1 has been attached. More specifically, the display (first housing 1) displays an image to be watched by the user sitting on the seat located behind the seat to which the display has been attached.

As illustrated in FIG. 2, first housing 1 includes first processor 11, first memory 12, first connector 13, and one or more (here, three) resistors R1. Hereinafter, when three resistors R1 need to be distinguished, three resistors R1 are referred to as resistor R11, resistor R12, and resistor R13.

First processor 11 is, for example, configured as a Digital Signal Processor (DSP), Central Processing Unit (CPU), Field Programable Gate Array (FPGA), or the like. First processor 11 operates according to a program and control data stored in first memory 12. First processor 11 performs a process for fulfilling a function of first housing 1. Moreover, when second connector 23 (to be described later) is connected to first connector 13, first processor 11 communicates with one or more modules 3 (to be described later) included in second housing 2 to perform a process for fulfilling a function of each of the one or more modules 3.

First memory 12 is, for example, semiconductor memory such as Random Access Memory (RAM), Read Only Memory (ROM), or the like. It should be noted that, for example, first memory 12 may be a recording medium such as flash memory, Hard Disk Drive (HDD), Solid State Drive (SSD), or the like. First memory 12 stores a program, data, and the like necessary for first processor 11 to perform various processes.

First connector 13 is a receptacle and includes a plurality of first terminals 131. Each of the plurality of first terminals 131 is connected to first processor 11. Moreover, when second connector 23 is connected to first connector 13, the plurality of first terminals 131 are connected one-to-one to a plurality of second terminals 231 included in second connector 23. Accordingly, when second connector 23 is connected to first connector 13, first processor 11 is connected to the plurality of second terminals 231 via the plurality of first terminals 131.

Resistor R1 is a pull-up resistor, and an end of resistor R1 is connected to power source 14 included in first housing 1. Another end of resistor R1 is connected to first terminal 131 among the plurality of first terminals 131 of first connector 13. In Embodiment 1, an end of each of three resistors R11, R12, and R13 is connected to power source 14. Moreover, another end of each of three resistors R11, R12, and R13 is connected to a different one of three first terminals 131.

Second housing 2 is connectable to first housing 1 and is, for example, a peripheral device attachable to and detachable from a display. Second housing 2 is also referred to as a “peripheral bar”. Second housing 2 is connected to first housing 1 to add a function of second housing 2 to first housing 1.

As illustrated in FIG. 2, second housing 2 includes first circuitry 21, second circuitry 22, and second connector 23.

First circuitry 21 includes an element for identifying the type of second housing 2. In Embodiment 1, the element is one or more (here, three) resistors R2, and the resistance value of resistor R2 varies depending on the type of second housing 2. Hereinafter, when three resistors R2 need to be distinguished, three resistors R2 are referred to as resistor R21, resistor R22, and resistor R23.

Resistor R2 is a pull-down resistor, and an end of resistor R2 is connected to a reference potential point of second housing 2. Another end of resistor R2 is connected to second terminal 231 among the plurality of second terminals 231 of second connector 23. In Embodiment 1, an end of each of three resistors R21, R22, and R23 is connected to the reference potential point. Moreover, another end of each of three resistors R21, R22, and R23 is connected to a different one of three second terminals 231.

When second connector 23 is connected to first connector 13, resistor R2 is connected to resistor R1 via second terminal 231 connected to resistor R2 and first terminal 131 connected to resistor R1. Accordingly, when second connector 23 is connected to first connector 13, a series circuit of resistor R1 and resistor R2 is established. In Embodiment 1, when second connector 23 is connected to first connector 13, three series circuits that are a series circuit of resistor R11 and resistor R21, a series circuit of resistor R12 and resistor R22, and a series circuit of resistor R13 and resistor 23 are established.

Second circuitry 22 includes one or more modules 3 among a plurality of modules 3 having different functions. The one or more modules 3 included in second circuitry 22 may vary depending on the type of second housing 2. In the example illustrated in FIG. 2, second circuitry 22 includes, as the one or more modules 3, module 3 as a functional button, module 3 as a light, module 3 as an audio codec, module 3 as a Bluetooth (registered trademark) module, and module 3 as a Universal Serial Bus Power Delivery (USB PD) controller. In other words, each of the plurality of modules 3 has a specific function. It should be noted that the one or more modules 3 included in second circuitry 22 are not limited to the above-listed modules 3 and may include other one or more modules 3. Moreover, the one or more modules 3 included in second circuitry 22 may include a plurality of modules 3 having the same function. Module 3 as a functional button is a module for adding, to first housing 1, an interface that is operable by a user. For example, when first housing 1 is a display, module 3 as a functional button may include a button for switching on and off a power source of the display, a button for changing an image displayed on the display, a button for adjusting the volume of sound outputted from the display, and the like.

Module 3 as a light is a module for adding, to first housing 1, a light for illuminating, for example, first housing 1 itself or the surroundings of first housing 1. For example, when first housing 1 is a display, module 3 as a light may include a light for illuminating the display itself or the surroundings of the display.

Module 3 as an audio codec is a module for encoding or decoding sound data. For example, when first housing 1 is a display, module 3 as an audio codec decodes sound data transmitted from the display and outputs the decoded sound data as sound.

Module 3 as a Bluetooth (registered trademark) module is a module for adding, to first housing 1, a Bluetooth (registered trademark) communication function. For example, when first housing 1 is a display, module 3 as a Bluetooth (registered trademark) module connects, to the display, an external device that is compatible with a Bluetooth (registered trademark) module and owned by a user, by communication using Bluetooth (registered trademark) technology. The external device is, for example, a wireless earphone or the like.

Module 3 as a USB PD controller is a module for adding, to first housing 1, a power supply function using a USB cable. For example, when first housing 1 is a display and connected to an external device, such as a smartphone owned by a user, via a USB cable, module 3 as a USB PD controller supplies electricity from a power source included in the display to a battery of the external device via the USB cable.

In Embodiment 1, the one or more modules 3 included in second circuitry 22 include first module 3A including memory (here, second memory 31). First module 3A is, for example, module 3 as an audio codec, module 3 as a USB PD controller, or the like.

Second memory 31 is, for example, semiconductor memory such as RAM or flash memory. Second memory 31 stores setting information, data, and the like to be referred by first module 3A. The setting information is information used for causing first module 3A to perform a predetermined operation. In Embodiment 1, when second connector 23 is connected to first connector 13, the setting information is written into second memory 31 by first processor 11 of first housing 1.

For example, when first module 3A is module 3 as an audio codec, the setting information is information about a setting of an amplifier of first housing 1. In other words, the setting information includes information about a sound signal transmitted from first housing 1.

Moreover, for example, when first module 3A is module 3 as a USB PD controller, the setting information is information about the power rating of first housing 1. In other words, the setting information includes information about voltage supplied from first housing 1.

Moreover, in Embodiment 1, the one or more modules 3 included in second circuitry 22 include second module 3B including third connector 32 that is connectable to an external device. Second module 3B is, for example, module 3 as an audio codec, module 3 as a USB PD controller, or the like. When second connector 23 is connected to first connector 13, first processor 11 and second module 3B perform an operation on the external device according to a function of second module 3B.

For example, when second module 3B is module 3 as an audio codec, third connector 32 is an earphone jack into which a plug of an external device such as an earphone or headphone can be inserted. In this case, first processor 11 and module 3 as an audio codec output, to the earphone or headphone connected to third connector 32, a sound signal that has been transmitted from first housing 1 and decoded.

Moreover, for example, when second module 3B is module 3 as an USB PD controller, third connector 32 is a USB connector into which a USB plug of an electronic device that is an external device such as a smartphone can be inserted. In this case, first processor 11 and module 3 as a USB PD controller supply power from power source 14 of first housing 1 to the electronic device connected to third connector 32.

Second connector 23 is a header and includes the plurality of second terminals 231 connectable to the plurality of first terminals 131 included in first connector 13 of first housing 1. Among the plurality of second terminals 231, one or more second terminals 231 are connected to the one or more modules 3 included in second circuitry 22. Moreover, other three second terminals 231 among the plurality of second terminals 231 are connected to three resistors R21, R22, and R23.

Second connector 23 is connected to first connector 13 to thereby connect first connector 13 to first circuitry 21 and second circuitry 22. In other words, second connector 23 is connected to first connector 13 to thereby connect three resistors R21, R22, and R23 included in first circuitry 21 to three first terminals 131 connected to three resistors R11, R12, and R13. Moreover, second connector 23 is connected to first connector 13 to thereby connect each of the one or more modules 3 included in second circuitry 22 to a corresponding one of one or more first terminals 131.

It should be noted that second connector 23 does not necessarily be a header and may be a receptacle. When second connector 23 is a receptacle, first connector 13 is a header. Moreover, it is sufficient if first connector 13 and second connector 23 are connectable to each other.

Here, in Embodiment 1, second housing 2 does not include a processor that communicates with first processor 11 of first housing 1. Specifically, second housing 2 includes the one or more modules 3 but does not include a general-purpose processor that comprehensively controls the one or more modules 3. In other words, in Embodiment 1, first processor 11 can initialize module 3 by writing setting information into memory (second memory 31) of module 3 (first module 3A), and thus first processor 11 can indirectly control operation of module 3. Accordingly, in Embodiment 1, second housing 2 does not need a CPU that controls the operation of module 3 since first processor 11 communicates with module 3. In other words, it is sufficient if second housing 2 includes a co-processor that is a processor dedicated to a specific use for playing an auxiliary role, and second housing 2 does not need to include a CPU. Therefore, Embodiment 1 has the advantage that cost for, for example, replacing second housing 2 in maintenance can be easily reduced since second housing 2 does not need to include a CPU.

### (2. Processes Performed by First Processor)

Hereinafter, processes performed by first processor 11 of first housing 1 are described in detail. When second connector 23 is connected to first connector 13, first processor 11 performs a process for identifying the type of second housing 2 by reading out information about an element for identifying the type of second housing 2 from first circuitry 21.

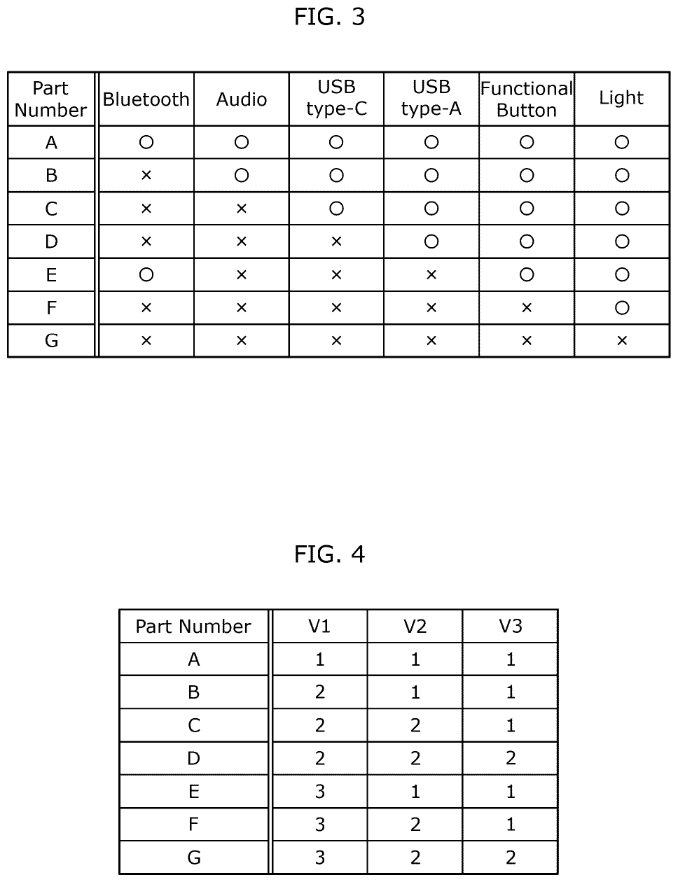

Here, a plurality of types of second housings 2 are described with reference to FIG. 3. FIG. 3 is a diagram illustrating an example of a plurality of types of second housings 2 that can be used in electronic device system 100 according to Embodiment 1. In FIG. 3, the column titled “Part Number” shows the type of second housing 2, the column titled “Bluetooth” shows whether second housing 2 includes module 3 as a Bluetooth (registered trademark) module, the column titled “Audio” shows whether second housing 2 includes module 3 as an audio codec, the column titled “USB Type-C” shows whether second housing 2 includes module 3 as a USB PD controller compatible with the USB Type-C standard, the column titled “USB Type-A” shows whether second housing 2 includes module 3 as a USB PD controller compatible with the USB Type-A standard, the column titled “Functional Button” shows whether second housing 2 includes module 3 as a functional button, and the column titled “Light” shows whether second housing 2 includes module 3 as a light. FIG. 3 shows, as an example, seven types of second housings 2 that are “A” to “G”. One or more modules 3 included in second housing 2 vary depending on the type of second housing 2 according to a request from a client. For example, when the type of second housing 2 is “A”, second housing 2 includes module 3 as a Bluetooth (registered trademark) module, module 3 as an audio codec, module 3 as a USB PD controller compatible with the USB Type-C standard, module 3 as a USB PD controller compatible with the USB Type-A standard, module 3 as a functional button, and module 3 as a light. Moreover, for example, when the type of second housing 2 is “E”, second housing 2 only includes module 3 as a Bluetooth (registered trademark) module, module 3 as a functional button, and module 3 as a light.

In Embodiment 1, first processor 11 includes an Analog to Digital Convertor (ADC), and when first connector 13 is connected to second connector 23, first processor 11 obtains voltage values from series circuits each of which includes resistor R1 and resistor R2. In other words, when second connector 23 is connected to first connector 13, first processor 11 reads out a voltage value applied to each resistor R2 (here, a divided voltage value of voltage supplied from power source 14). Accordingly, in Embodiment 1, the voltage value applied to each resistor R2 is equivalent to the information about an element for identifying the type of second housing 2.

Specifically, first processor 11 performs analog-to-digital conversion on a divided voltage value that is a divided voltage value of voltage supplied from power source 14 and has been inputted from a series circuit of resistor R11 and resistor R21, to thereby obtain the divided voltage value of the voltage supplied from power source 14 in the series circuit. Moreover, first processor 11 performs analog-to-digital conversion on a divided voltage value that is a divided voltage value of voltage supplied from power source 14 and has been inputted from a series circuit of resistor R12 and resistor R22, to thereby obtain the divided voltage value of the voltage supplied from power source 14 in the series circuit. Furthermore, first processor 11 performs analog-to-digital conversion on a divided voltage value that is a divided voltage value of voltage supplied from power source 14 and has been inputted from a series circuit of resistor R13 and resistor R23, to thereby obtain the divided voltage value of the voltage supplied from power source 14 in the series circuit.

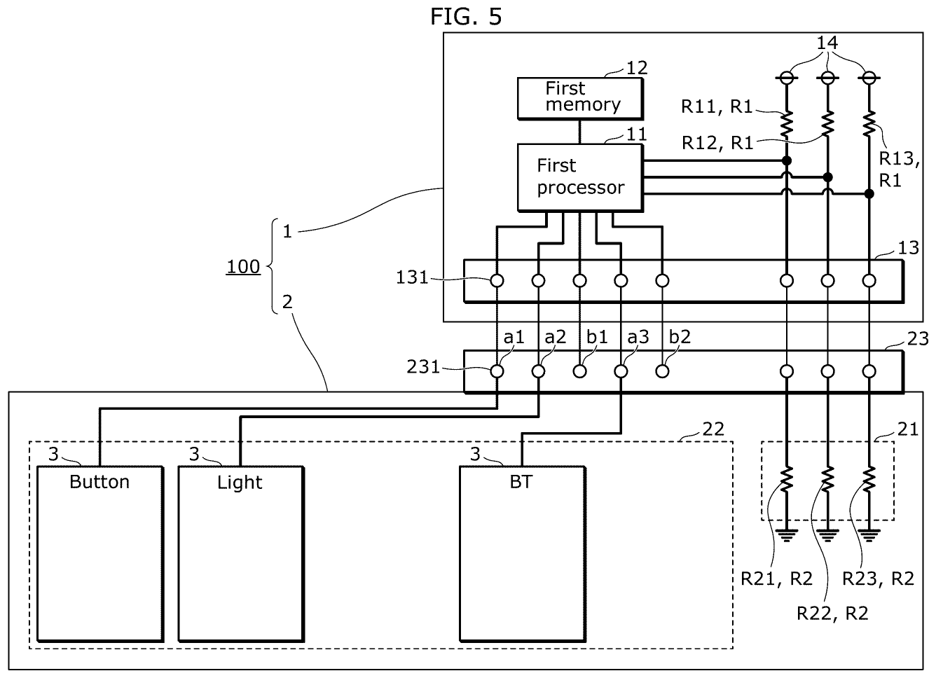

FIG. 4 is a diagram for describing an identification process for identifying the type of second housing 2 in electronic device system 100 according to Embodiment 1. FIG. 4 is a diagram illustrating correlation between the type of second housing 2 and divided voltage values of voltage supplied from power source 14 that are read out from series circuits each of which includes resistor R1 and resistor R2. In FIG. 4, the column titled “V1” shows a value obtained by normalizing a divided voltage value of voltage supplied from power source 14 that is read out from a series circuit of resistor R11 and resistor R21. Moreover, the column titled “V2” shows a value obtained by normalizing a divided voltage value of voltage supplied from power source 14 that is read out from a series circuit of resistor R12 and resistor R22. Furthermore, the column titled “V3” shows a value obtained by normalizing a divided voltage value of voltage supplied from power source 14 that is read out from a series circuit of resistor R13 and resistor R23.

First processor 11 identifies the type of second housing 2 based on divided voltage values of voltage supplied from power source 14 that are read out from series circuits each of which includes resistor R1 and resistor R2. In the example illustrated in FIG. 4, first processor 11 identifies the type of second housing 2 based on a combination of “V1”, “V2”, and “V3”. For example, when “V1” is “1”, “V2” is “1”, and “V3” is “1”, first processor 11 identifies that the type of second housing 2 is “A”. Moreover, for example, when “V1” is “3”, “V2” is “2”, and “V1” is “1”, first processor 11 identifies that the type of second housing 2 is “F”.

Moreover, first processor 11 communicates with second circuitry 22 via, among the plurality of second terminals 231, one or more second terminals 231 connected to one or more modules 3 that are used for the type identified and does not communicate with second circuitry 22 via second terminal 231 other than the one or more second terminals 231. In other words, first processor 11 communicates with, among the plurality of second terminals 231, one or more second terminals 231 connected to one or more modules 3 that are used for the type identified; however, does not attempt to communicate with other one or more second terminals 231 assigned for one or more modules 3 that are not used for the type identified.

FIG. 5 is a schematic diagram illustrating a usage example of electronic device system 100 according to Embodiment 1. In the example illustrated in FIG. 5, the type of second housing 2 is “E”, and second housing 2 only includes module 3 as a Bluetooth (registered trademark) module, module 3 as a functional button, and module 3 as a light. When second connector 23 is connected to first connector 13, first processor 11 identifies that the type of second housing 2 is “E” by performing the identification process. Then, first processor 11 communicates with one or more (here, three) modules 3 that are used for the type “E”, via one or more (here, three) second terminals 231 among a plurality of (here, five) second terminals 231 of second connector 23. In contrast, first processor 11 does not attempt to communicate with one or more (here, two) second terminals 231 other than the one or more second terminals 231 connected to the one or more modules 3 that are used for the type “E”.

More specifically, first processor 11 communicates with module 3 as a Bluetooth (registered trademark) module, module 3 as a functional button, and module 3 as a light, via only three second terminals 231 (“a1”, “a2”, and “a3” in FIG. 5) connected to those modules 3. In contrast, first processor 11 does not attempt to communicate with two second terminals 231 (“b1” and “b2” in FIG. 5) each of which is not connected to module 3.

Moreover, when second connector 23 is connected to first connector 13, processor 11 performs a process of writing setting information into memory (second memory 31) of first module 3A based on the type identified. For example, when the type identified is “B”, first processor 11 can recognize that second housing 2 includes, as first modules 3A, module 3 as an audio codec and module 3 as a USB PD controller. Then, first processor 11 performs a process of writing setting information about module 3 as an audio codec into memory (second memory 31) of module 3 as an audio codec.

Moreover, first processor 11 performs a process of writing setting information about module 3 as a USB PD controller into memory (second memory 31) of module 3 as a USB PD controller.

It should be noted that, in Embodiment 1, when one or more modules 3 included in second circuitry 22 includes one of a plurality of types of modules 3 having the same function, first processor 11 identifies the one of the plurality of types of modules 3 having the same function based on the type of second housing 2 identified. For example, when the plurality of types of modules 3 having the same function are a plurality of modules 3 each having a function as an audio codec, the plurality of modules 3 having the same function may be different in the type of codec from one another. Moreover, for example, when the plurality of modules 3 having the same function are a plurality of modules 3 each having a function as a Bluetooth (registered trademark) module, the plurality of modules 3 having the same function may be different in the version of Bluetooth from one another. Furthermore, for example, when the plurality of modules 3 having the same function are a plurality of modules 3 each having a function as a USB PD controller, the plurality of modules 3 having the same function may be different in the shape of USB connector, such as Type-A and Type-C, or in the number of connectors from one another.

In Embodiment 1, since first processor 11 can identify module 3 included in second housing 2 identified among a plurality of types of modules 3 having the same function based on the type of second housing 2 identified, first processor 11 can perform a process corresponding to module 3 identified.

### (3. Operation)

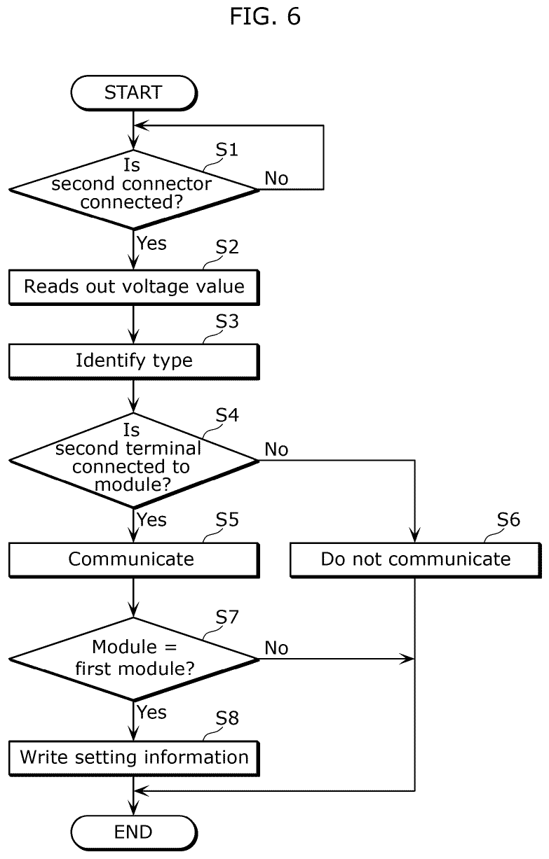

Hereinafter, operation of electronic device system 100 according to Embodiment 1 is described with reference to FIG. 6. First, when second connector 23 of second housing 2 is not connected to first connector 13 of first housing 1 (S1: No), first processor 11 of first housing 1 does not perform a process on second housing 2. Then, when second connector 23 is connected to first connector 13 (S1: Yes), first processor 11 reads out a voltage value applied to resistor R2 (here, a divided voltage value of voltage supplied from power source 14) to thereby obtain information about an element for identifying the type of second housing 2 from first circuitry 21 of second housing 2 (S2).

Next, first processor 11 identifies the type of second housing 2 based on the divided voltage value of voltage supplied from power source 14 read out (S3). Then, when second terminal 231 of second connector 23 is connected to module 3 (S4: Yes), first processor 11 communicates with the module 3 via the second terminal 231. In contrast, when second terminal 231 of second connector 23 is not connected to module 3 (S4: No), first processor 11 does not attempt to communicate with the second terminal 231 (S6).

Moreover, when the module 3 connected to the second terminal 231 is first module 3A (S7: Yes), first processor 11 writes setting information about the first module 3A into memory (second memory 31) of the first module 3A (S8). It should be noted that when the module 3 connected to the second terminal 231 is not first module 3A (S7: No), first processor 11 does not perform a process of writing setting information.

### (4. Advantages)

Hereinafter, advantages of electronic device system 100 according to Embodiment 1 are described by comparing with an electronic device system according to a comparative example. The electronic device system according to the comparative example is different from electronic device system 100 according to Embodiment 1 in that a first processor of a first housing of the electronic device system according to the comparative example does not identify the type of a second housing and attempts to communicate with all of second terminals of a second connector.

Since the electronic device system according to the comparative example attempts to communicate with all of the second terminals regardless of the type of the second housing, the electronic device system according to the comparative example attempts to communicate with even a second terminal that is not connected to a module. In this case, when an anomaly occurs in communication for a second terminal, the first processor of the electronic device system according to the comparative example cannot determine whether the anomaly is due to an anomaly occurred in a module connected to the second terminal or due to the fact that the second terminal is not connected to a module.

In contrast, in electronic device system 100 according to Embodiment, when second connector 23 is connected to first connector 13, first processor 11 identifies the type of second housing 2. Then, first processor 11 communicates with, among a plurality of second terminals 231 of second connector 23, one or more second terminals 231 connected to one or more modules 3 that are used for the type identified, and does not attempt to communicate with other one or more second terminals 231 that are not used for the type identified.

Therefore, electronic device system 100 according to Embodiment 1 has the advantage that whether one or more modules 3 that are used for the type identified are operating properly or not can be easily determined since electronic device system 100 does not attempt to communicate with one or more second terminals 231 that are not used for the type identified. In other words, electronic device system 100 according to Embodiment 1 has the advantage that a function of one or more modules 3 included in second housing 2 connected to first housing 1 can be easily fulfilled. Moreover, electronic device system 100 according to Embodiment 1 has the advantage that the compatibility of first housing 1 with second housing 2 can be easily secured since first housing 1 can be connected to various second housings 2 for use.

### Embodiment 2

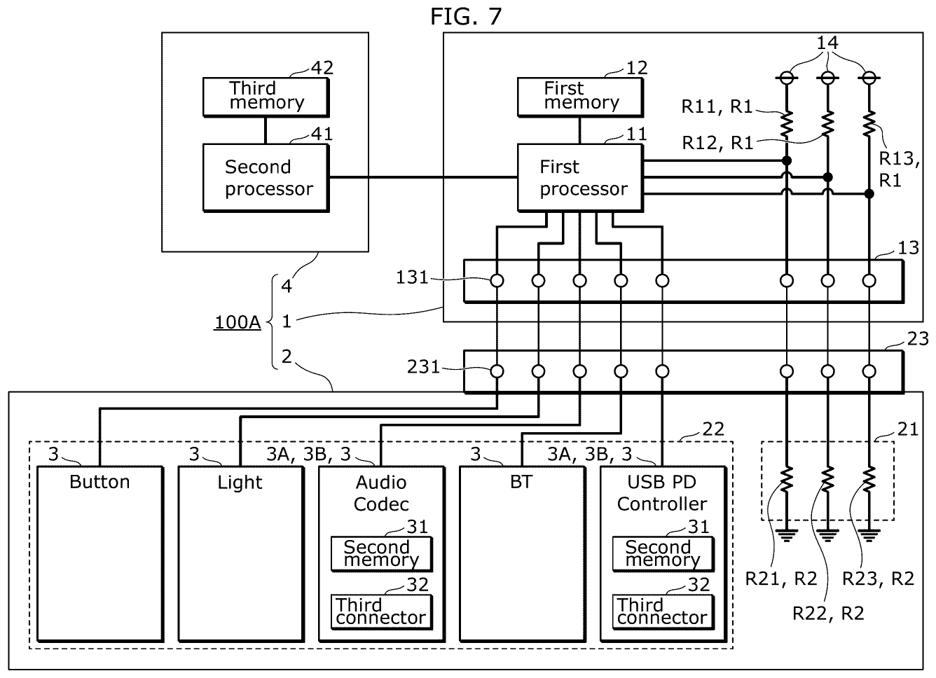

Hereinafter, electronic device system 100A according to Embodiment 2 is described with reference to FIG. 7. FIG. 7 is a block diagram illustrating a configuration of electronic device system 100A according to Embodiment 2. As illustrated in FIG. 7, electronic device system 100A according to Embodiment 2 is different from electronic device system 100 according to Embodiment 1 in that electronic device system 100A further includes third housing 4 in addition to first housing 1 and second housing 2. It should be noted that, hereinafter, a detailed description of a configuration common to electronic device system 100 according to Embodiment 1 is omitted.

Third housing 4 is separate from first housing 1 and stored, for example, below a seat of a moving body. Third housing 4 is also referred to as a seat box. As illustrated in FIG. 7, third housing 4 includes second processor 41 and third memory 42.

Second processor 41 is, for example, configured as a DSP, CPU, FPGA, or the like. Moreover, when first housing 1 is a display, second processor 41 may be a Graphics Processing Unit (GPU) for performing image processing on the display. Second processor 41 operates according to a program and control data stored in third memory 42.

Second processor 41 performs a process for fulfilling a function of third housing 4. For example, when electronic device system 100A includes a plurality of first housings 1, second processor 41 performs a process for supplying a power source to each of the plurality of first housings 1 or a process for transmitting content to each of the plurality of first housings 1 by communicating with a content server provided to the moving body.

Moreover, when second connector 23 is connected to first connector 13, second processor 41 may communicate with one or more predetermined modules 3 among one or more modules 3 included in second housing 2 to thereby perform a process for fulfilling, in first housing 1, a function of the one or more predetermined modules 3. In this case, first processor 11 transmits, to second processor 41, one of information about an element for identifying the type of second housing 2 read out or information about the type identified. Thus, second processor 41 can perform a process corresponding to the type of second housing 2. For example, when second housing 2 includes one or more predetermined modules 3, second processor 41 communicates with one or more second terminals 231 connected to the one or more predetermined modules 3; however, when second housing 2 includes no predetermined module 3, second processor 41 does not attempt to communicate with any second terminal 231.

It should be noted that, in the example illustrated in FIG. 7, when second connector 23 is connected to first connector 13, second processor 41 is indirectly connected to one or more predetermined modules 3 via first processor 11; however, second processor 41 may be directly connected to some or all of the one or more predetermined modules 3 without using first processor 11. In this case, the one or more predetermined modules 3 directly communicate with second processor 41 via one or more second terminals 231. Thus, at least part of communication that is performed via first processor 11 can be reduced and a processing load of first processor 11 can be reduced.

Moreover, second processor 41 may be directly connected to first circuitry 21 without using first processor 11, in addition to some or all of the one or more predetermined modules 3. In this case, second processor 41 can obtain information about an element for identifying the type of second housing 2 directly from first circuitry 21.

Third memory 42 is, for example, semiconductor memory such as RAM or ROM. It should be noted that third memory 42 may be, for example, a recording medium such as flash memory, HDD, or SSD. Third memory 42 stores a program, data, and the like necessary for second processor 41 to perform various processes.

### Other Embodiments

Although an electronic device system according to the present disclosure has been described based on Embodiments 1 and 2, the present disclosure is not limited to Embodiments 1 and 2.

Each of electronic device systems 100 and 100A according to Embodiments 1 and 2 may include circuitry other than first circuitry 21 and second circuitry 22. For example, second housing 2 may include circuitry including a sensor and may communicate with first housing 1 by the circuitry.

Moreover, although each of the number of resistors R1 and the number of resistors R2 is three in Embodiments 1 and 2, the present disclosure is not limited to this example. For example, each of the number of resistors R1 and the number of resistors R2 may be two or less or four or more. Each of the number of resistors R1 and the number of resistors R2 may increase or decrease according to the number of types of second housings 2 that can be identified by an identification process performed by first processor 11. In other words, each of the number of resistors R1 and the number of resistors R2 may increase as the number of types of second housings 2 that can be identified by first processor 11 increases, and each of the number of resistors R1 and the number of resistors R2 may decrease as the number of types of second housings 2 that can be identified by first processor 11 decreases.

For example, although first circuitry 21 of second housing 2 includes resistor R2 as an element for identifying the type of second housing 2 in Embodiments 1 and 2, the present disclosure is not limited to this example. For example, first circuitry 21 may include, as an element for identifying the type of second housing 2, flash memory storing identification information, such as a serial number, that can be used for identifying the type of second housing 2. In this case, when second connector 23 is connected to first connector 13, first processor 11 of first housing 1 may read out the identification information by communicating with the flash memory and identify the type of second housing 2 based on the identification information read out. In this case, first housing 1 does not need to include resistor R1.

For example, processors included in the electronic device system according to Embodiments 1 and 2 are typically realized as a Large-Scale Integration (LSI) circuit that is an integrated circuit. The processors may be individually realized as a single chip, or some or all of the processors may be realized as a single chip.

For example, first housing 1 in each of electronic device systems 100 and 100A according to Embodiments 1 and 2 may be distributed as a single product, such as an electronic device described below, in the market. An electronic device (first housing 1) is an electronic device that is provided to a moving body, includes first processor 11 and first connector 13 including a plurality of first terminals 131, and is connectable to a predetermined electronic device (second housing 2) that is further provided to the moving body. The predetermined electronic device (second housing 2) includes first circuitry 21, second circuitry 22, and second connector 23. First circuitry 21 includes an element (resistor R2) for identifying the type of the predetermined electronic device (second housing 2). Second circuitry 22 is connected to one or more modules 3 among a plurality of modules 3 having different functions. Second connector 23 includes a plurality of second terminals 231 connectable to the plurality of first terminals 131 and connects first connector 13 to first circuitry 21 and second circuitry 22. When second connector 23 is connected to first connector 13, first processor 11 identifies the type of the predetermined electronic device (second housing 2) by reading out information about the element from first circuitry 21. First processor 11 communicates with second circuitry 22 via, among the plurality of second terminals 231, one or more second terminals 231 connected to one or more modules 3 that are used for the type identified and does not communicate with second circuitry 22 via second terminal 231 other than the one or more second terminals 231. Moreover, for example, second housing 2 in each of electronic device systems 100 and 100A according to Embodiments 1 and 2 may be distributed as a single product, such as an electronic device described below, in the market. An electronic device (second housing 2) is an electronic device that is provided to a moving body and connectable to a predetermined electronic device (first housing 1) that is further provided to the moving body. The electronic device (second housing 2) includes first circuitry 21 and second circuitry 22. First circuitry 21 includes an element (resistor R2) for identifying the type of the electronic device (second housing 2). Second circuitry 22 is connected to one or more modules 3 among a plurality of modules 3 having different functions. When first circuitry 21 is connected to the predetermined electronic device (first housing 1), first circuitry 21 provides information about the element to the predetermined electronic device (first housing 1).

Moreover, circuit integration is not limited to an LSI. The processors may be realized as dedicated circuits or generic processors. An FPGA that can be programmed after an LSI is manufactured or a reconfigurable processor that can reconfigure the setting or connection of circuit cells inside an LSI may be used.

It should be noted that, in the above-described embodiments, a processor may be configured as dedicated hardware or realized by executing a software program suitable to each constituent element. Each constituent element may be realized by a program executor, such as a CPU or processor, reading out and executing a software program stored in a recording medium such as a hard disk or semiconductor memory.

### (Conclusion)

As described above, each of electronic device systems 100 and 100A according to a first aspect of the present disclosure includes first housing 1 and second housing 2. First housing 1 is provided to a moving body and includes first processor 11 and first connector 13 including a plurality of first terminals 131. Second housing 2 is provided to the moving body and connectable to first housing 1. Second housing 2 includes first circuitry 21, second circuitry 22, and second connector 23. First circuitry 21 includes an element (resistor R2) for identifying the type of second housing 2. Second circuitry 22 is connected to one or more modules 3 among a plurality of modules 3 having different functions. Second connector 23 includes a plurality of second terminals 231 connectable to the plurality of first terminals 131 and connects first connector 13 to first circuitry 21 and second circuitry 22. When second connector 23 is connected to first connector 13, first processor 11 reads out information about the element from first circuitry 21 to identify the type of second housing 2. First processor 11 communicates with second circuitry 22 via, among the plurality of second terminals 231, one or more second terminals 231 connected to the one or more modules 3 used for the type identified, and does not communicate with second circuitry 22 via second terminal 231 other than the one or more second terminals 231.

With this configuration, since communication with one or more second terminals 231 that are not used for the type identified is not attempted, there is the advantage that whether the one or more modules 3 used for the type identified are operating properly or not can be easily determined. In other words, with this configuration, there is the advantage that a function of the one or more modules 3 included in second housing 2 connected to first housing 1 can be easily fulfilled.

Each of electronic device systems 100 and 100A according to a second aspect of the present disclosure is the electronic device system according to the first aspect. In the second aspect, the element is one or more resistors R2. When second connector 23 is connected to first connector 13, first processor 11 reads out a voltage value applied to the one or more resistors R2 to identify the type of second housing 2.

With this configuration, since the type of second housing 2 can be identified in first housing 1 by only providing one or more resistors R2 to second housing 2, there is the advantage that the manufacturing cost of second housing 2 can be easily reduced.

Each of electronic device systems 100 and 100A according to a third aspect of the present disclosure is the electronic device system according to the first or second aspect. In the third aspect, the one or more modules 3 include first module 3A including memory (second memory 31). When second connector 23 is connected to first connector 13, first processor 11 writes, into the memory (second memory 31), setting information for causing first module 3A to perform a predetermined operation, based on the type identified.

With this configuration, since first processor 11 can initialize module 3 and indirectly control operation of module 3 by writing setting information into memory (second memory 31) of module 3 (first module 3A), there is the advantage that second housing 2 does not need to include a general-purpose processor for communicating with first processor 11 to control the operation of module 3.

Each of electronic device systems 100 and 100A according to a fourth aspect of the present disclosure is the electronic device system according to the third aspect. In the fourth aspect, first module 3A is a Universal Serial Bus Power Delivery (USB PD) controller. The setting information includes information about voltage supplied from first housing 1.

With this configuration, there is the advantage that an external device connected to second housing 2 can be charged with proper supply voltage.

Each of electronic device systems 100 and 100A according to a fifth aspect of the present disclosure is the electronic device system according to the third aspect. In the fifth aspect, first module 3A is an audio codec. The setting information includes information about a sound signal transmitted from first housing 1.

With this configuration, there is the advantage that sound based on the sound signal transmitted from first housing 1 can be outputted with proper sound volume.

Each of electronic device systems 100 and 100A according to a sixth aspect of the present disclosure is the electronic device system according to any one of the first to fifth aspects. In the sixth aspect, the one or more modules 3 include one of a plurality of types of modules 3 having the same function. First processor 11 identifies the one of the plurality of types of modules 3 having the same function, based on the type identified.

With this configuration, since first processor 11 can identify which of the plurality of types of modules 3 having the same function is module 3 included in second housing 2, there is the advantage that first processor 11 can perform a process corresponding to module 3 identified.

Each of electronic device systems 100 and 100A according to a seventh aspect of the present disclosure is the electronic device system according to any one of the first to sixth aspects. In the seventh aspect, second housing 2 does not include a central processing unit (CPU) that communicates with first processor 11 of first housing 1.

With this configuration, since second housing 2 does not need to include a CPU, there is the advantage that cost for, for example, replacing second housing 2 in maintenance can be easily reduced.

Each of electronic device systems 100 and 100A according to an eighth aspect of the present disclosure is the electronic device system according to any one of the first to seventh aspects. In the eighth aspect, the one or more modules 3 include second module 3B including third connector 32 connectable to an external device. When second connector 23 is connected to first connector 13, first processor 11 and second module 3B perform, on the external device, operation corresponding to a function of second module 3B.

With this configuration, there is the advantage that first housing 1 and second housing 2 can cooperate to perform operation on the external device.

Electronic device system 100A according to a ninth aspect of the present disclosure is the electronic device system according to any one of the first to eighth aspects. In the ninth aspect, electronic device system 100A further includes third housing 4. Third housing 4 is separate from first housing 1 and includes second processor 41. When second connector 23 is connected to first connector 13, first processor 11 transmits, to second processor 41, one of the information about the element read out or information about the type identified.

With this configuration, there is the advantage that second processor 41 can also perform a process corresponding to the type of second housing 2.

Electronic device system 100A according to a tenth aspect of the present disclosure is the electronic device system according to any one of the first to eighth aspects. In the tenth aspect, electronic device system 100A further includes third housing 4. Third housing 4 is separate from first housing 1 and includes second processor 41. When second connector 23 is connected to first connector 13, second processor 41 reads out, without using first processor 11, the information about the element to identify the type of second housing 2, and communicates with, without using first processor 11, at least some of the one or more modules 3 connected to second circuitry 22.

With this configuration, there is the advantage that at least part of communication via first processor 11 can be reduced and a processing load of first processor 11 can be reduced.

An electronic device (first housing 1) according to an eleventh aspect of the present disclosure is provided to a moving body, includes first processor 11 and first connector 13 including a plurality of first terminals 131, and is connectable to a predetermined electronic device (second housing 2) that is provided to the moving body. The predetermined electronic device (second housing 2) includes first circuitry 21, second circuitry 22, and second connector 23. First circuitry 21 includes an element (resistor R2) for identifying the type of the predetermined electronic device (second housing 2). Second circuitry 22 is connected to one or more modules 3 among a plurality of modules 3 having different functions. Second connector 23 includes a plurality of second terminals 231 connectable to the plurality of first terminals 131 and connects first connector 13 to first circuitry 21 and second circuitry 22. When second connector 23 is connected to first connector 13, first processor 11 reads out information about the element from first circuitry 21 to identify the type of the predetermined electronic device (second housing 2). First processor 11 communicates with second circuitry 22 via, among the plurality of second terminals 231, one or more second terminals 231 connected to the one or more modules 3 used for the type identified, and does not communicate with second circuitry 22 via second terminal 231 other than the one or more second terminals 231.

With this configuration, since communication with one or more second terminals 231 that are not used for the type identified is not attempted, there is the advantage that whether the one or more modules 3 used for the type identified are operating properly or not can be easily determined. In other words, with this configuration, there is the advantage that a function of the one or more modules 3 included in the predetermined electronic device (second housing 2) connected to the electronic device (first housing 1) can be easily fulfilled.

An electronic device (second housing 2) according to a twelfth aspect of the present disclosure is provided to a moving body and connectable to a predetermined electronic device (first housing 1) that is provided to the moving body. The electronic device (second housing 2) includes first circuitry 21 and second circuitry 22. First circuitry 21 includes an element (resistor R2) for identifying the type of the electronic device (second housing 2). Second circuitry 22 is connected to one or more modules 3 among a plurality of modules 3 having different functions. When the electronic device (second housing 2) is connected to the predetermined electronic device (first housing 1), first circuitry 21 provides information about the element to the predetermined electronic device (first housing 1).

With this configuration, there is the advantage that the type of the electronic device (second housing 2) can be identified in the predetermined electronic device (first housing 1), based on the information about the element.

Although exemplary embodiments have been described above, the scope of the Claims of the present application is not limited to these embodiments. Those skilled in the art will readily appreciate that various modifications may be made in these exemplary embodiments and that other embodiments may be obtained by arbitrarily combining the constituent elements of these exemplary embodiments without departing from the novel teachings and advantages of the subject matter recited in the appended Claims. Accordingly, such modifications and other embodiments are included in the present disclosure.

### INDUSTRIAL APPLICABILITY

An electronic device system and electronic device according to the present disclosure are applicable to, for example, a display or the like installed in a moving body such as an airplane.

1. An electronic device system comprising:
a first housing that is provided to a moving body and includes a first processor and a first connector including a plurality of first terminals; and
a second housing that is provided to the moving body and connectable to the first housing, wherein
the second housing includes:
first circuitry including an element for identifying a type of the second housing;
second circuitry connected to one or more modules among a plurality of modules having different functions; and
a second connector that includes a plurality of second terminals connectable to the plurality of first terminals and connects the first connector to the first circuitry and the second circuitry, and
when the second connector is connected to the first connector, the first processor:
reads out information about the element from the first circuitry to identify the type of the second housing; and
communicates with the second circuitry via, among the plurality of second terminals, one or more second terminals connected to the one or more modules used for the type identified, and does not communicate with the second circuitry via a second terminal other than the one or more second terminals.

2. The electronic device system according to claim 1, wherein
the element is one or more resistors, and
when the second connector is connected to the first connector, the first processor reads out a voltage value applied to the one or more resistors to identify the type of the second housing.

3. The electronic device system according to claim 1, wherein
the one or more modules include a first module including memory, and
when the second connector is connected to the first connector, the first processor writes, into the memory, setting information for causing the first module to perform a predetermined operation, based on the type identified.

4. The electronic device system according to claim 3, wherein
the first module is a Universal Serial Bus Power Delivery (USB PD) controller, and
the setting information includes information about voltage supplied from the first housing.

5. The electronic device system according to claim 3, wherein
the first module is an audio codec, and
the setting information includes information about a sound signal transmitted from the first housing.

6. The electronic device system according to claim 1, wherein
the one or more modules include one of a plurality of types of modules having a same function, and
the first processor identifies the one of the plurality of types of modules having the same function, based on the type identified.

7. The electronic device system according to claim 1, wherein
the second housing does not include a central processing unit (CPU) that communicates with the first processor of the first housing.

8. The electronic device system according to claim 1, wherein
the one or more modules include a second module including a third connector connectable to an external device, and
when the second connector is connected to the first connector, the first processor and the second module perform, on the external device, operation corresponding to a function of the second module.

9. The electronic device system according to claim 1, further comprising:
a third housing that is separate from the first housing and includes a second processor, wherein
when the second connector is connected to the first connector, the first processor transmits, to the second processor, one of the information about the element read out or information about the type identified.

10. The electronic device system according to claim 1, further comprising:
a third housing that is separate from the first housing and includes a second processor, wherein
when the second connector is connected to the first connector, the second processor:
reads out, without using the first processor, the information about the element to identify the type of the second housing, and
communicates with, without using the first processor, at least some of the one or more modules connected to the second circuitry.

11. An electronic device that is provided to a moving body, the electronic device comprising:
a first processor; and
a first connector including a plurality of first terminals, wherein
the electronic device is connectable to a predetermined electronic device that is provided to the moving body and includes:
first circuitry including an element for identifying a type of the predetermined electronic device; second circuitry including one or more modules among a plurality of modules having different functions; and a second connector that includes a plurality of second terminals connectable to the plurality of first terminals and connects the first connector to the first circuitry and the second circuitry, and
when the second connector is connected to the first connector, the first processor:
reads out information about the element from the first circuitry to identify the type of the predetermined electronic device; and
communicates with the second circuitry via, among the plurality of second terminals, one or more second terminals connected to the one or more modules used for the type identified, and does not communicate with the second circuitry via a second terminal other than the one or more second terminals.

12. An electronic device that is provided to a moving body and connectable to a predetermined electronic device that is provided to the moving body, the electronic device comprising:
first circuitry including an element for identifying a type of the electronic device; and
second circuitry including one or more modules among a plurality of modules having different functions, wherein
when the electronic device is connected to the predetermined electronic device, the first circuitry provides information about the element to the predetermined electronic device.
